(19) United States
(12) Patent Application Publication
(10) Pub. No.: US 2024/0429096 A1
(43) Pub. Date: Dec. 26, 2024

(54) GATE CUT OF SELF-ALIGNED CONTACT POST REPLACEMENT METAL GATE

(71) Applicant: International Business Machines Corporation, Armonk, NY (US)

(72) Inventors: Chanro Park, Clifton Park, NY (US); Ruilong Xie, Niskayuna, NY (US); Min Gyu Sung, Latham, NY (US); Julien Frougier, Albany, NY (US); Juntao Li, Cohoes, NY (US)

(21) Appl. No.: 18/338,465

(22) Filed: Jun. 21, 2023

(51) Int. Cl. H01L 21/768; H01L 21/8234; H01L 27/088; H01L 29/66

(52) U.S. Cl. CPC H01L 21/76897; H01L 21/823431; H01L 21/823475; H01L 27/0886; H01L 29/66795

(57) ABSTRACT

A semiconductor device is provided and includes gate regions interleaved between interlayer dielectric (ILD) regions, field effect transistor (FET) structures extending across the gate regions and the ILD regions, source and drain (S/D) regions, shared between the gate regions, at exterior ones of the ILD regions, dielectric material between the FET structures and bisecting the gate regions and the ILD regions, liner material and contacts. The liner material is disposed on opposite sides of the dielectric material in the gate regions and not in the ILD regions. The contacts are formed about the FET structures in the exterior ones of the ILD regions and across the dielectric material at an interior one of the ILD regions.

### BACKGROUND

The present invention generally relates to fabrication methods and resulting structures for semiconductor devices. More specifically, the present invention relates to a gate cut of a self-aligned contact (SAC) post replacement metal gate (RMG).

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### SUMMARY

Embodiments of the invention are directed to a semiconductor device. A non-limiting example of the semiconductor device includes gate regions interleaved between interlayer dielectric (ILD) regions, field effect transistor (FET) structures extending across the gate regions and the ILD regions, source and drain (S/D) regions, shared between the gate regions, at exterior ones of the ILD regions, dielectric material between the FET structures and bisecting the gate regions and the ILD regions, liner material and contacts. The liner material is disposed on opposite sides of the dielectric material in the gate regions and not in the ILD regions. The contacts are formed about the FET structures in the exterior ones of the ILD regions and across the dielectric material at an interior one of the ILD regions.

Embodiments of the present invention are directed to a method of semiconductor device fabrication. A non-limiting example of the method includes forming a self-aligned cap (SAC) over field effect transistor (FET) structures, patterning a gate cut etch mask for opening gates, spacers and interlayer dielectric (ILD) of the FET structures, etching material exposed by the gate cut etch mask to a depth deeper than a bottom of the gates to form an opening, forming an overhang of the gate cut etch mask over the ILD, depositing a liner material on sidewalls of the gates and the spacers but not on the ILD under the overhang in the opening, removing the gate cut etch mask and filling a remainder of the opening with dielectric material.

Embodiments of the present invention are directed to semiconductor device. A non-limiting example of the semiconductor device includes a substrate, which includes vertical fins and first dielectric material interposed between the vertical fins, field effect transistor (FET) structures on the vertical fins, first liner material disposed over the FET structures and side portions of the first dielectric material, interlayer dielectric (ILD) disposed on the first liner material, second dielectric material extending through the ILD and into the first dielectric material and columnar liner material interposed between the first dielectric material and the second dielectric material and between respective lower portions of the ILD and the second dielectric material.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a top-down view of a semiconductor device according to one or more embodiments of the present invention;

FIG. 2 is a flow diagram illustration a method of semiconductor device fabrication in accordance with one or more embodiments of the present invention;

FIG. 3 is a top-down view of a semiconductor device assembly being fabricated in accordance with one or more embodiments of the present invention;

FIG. 4 is a side, cross-sectional view of a semiconductor device assembly at an initial stage of assembly taken along line “a” of FIG. 3 in accordance with one or more embodiments of the present invention;

FIG. 5 is a side, cross-sectional view of a semiconductor device assembly at an initial stage of assembly taken along line “b” of FIG. 3 in accordance with one or more embodiments of the present invention;

FIG. 6 is a side, cross-sectional view of a semiconductor device assembly at an initial stage of assembly taken along line “c” of FIG. 3 in accordance with one or more embodiments of the present invention;

FIG. 7 is a side, cross-sectional view of a semiconductor device assembly at a first intermediate stage of assembly taken along line “b” of FIG. 3 following gate cut hard mask patterning applied to the semiconductor device assembly of FIG. 3 and of FIGS. 4-6 in accordance with one or more embodiments of the present invention;

FIG. 8 is a side, cross-sectional view of a semiconductor device assembly at a second intermediate stage of assembly taken along line “b” of FIG. 3 following gate cut processing and subsequent selective etching processing applied to the semiconductor device assembly of FIG. 7 in accordance with one or more embodiments of the present invention;

FIG. 9 is a side, cross-sectional view of a semiconductor device assembly at a third intermediate stage of assembly taken along line “b” of FIG. 3 following liner or SiN deposition applied to the semiconductor device assembly of FIG. 8 in accordance with one or more embodiments of the present invention;

FIG. 10 is a side, cross-sectional view of a semiconductor device assembly at a fourth intermediate stage of assembly taken along line “b” of FIG. 3 following liner or SiN etching, gate cut mask removal and sequential depositions of second dielectric material and chemical mechanical polishing (CMP) applied to the semiconductor device assembly of FIG. 9 in accordance with one or more embodiments of the present invention;

FIG. 11 is a side, cross-sectional view of a semiconductor device assembly at a near-final stage of assembly taken along line “b” of FIG. 3 following source/drain (S/D) contact lithography and S/D contact etching applied to the semiconductor device assembly of FIG. 10 in accordance with one or more embodiments of the present invention; and

FIG. 12 is a side, cross-sectional view of a semiconductor device assembly at final stage(s) of assembly taken along line “b” of FIG. 3 following contact metallization applied to the semiconductor device assembly of FIG. 11 in accordance with one or more embodiments of the present invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, a post RMG gate cut process removes all exposed materials including those of a gate stack and interlayer dielectric (ILD). The cut area is then filled with a silicon nitride (SiN) liner followed by silicon dioxide (SiO2). It has been found, however, that some devices, such as static random access memory (SRAM) devices, require shared sources and drains (S/D). Hence, S/D contacts in these or other cases need to extend across the gate cut.

As gate pitch continues to get smaller over time, it is becoming difficult to do non-selective S/D contact etching. This is because such etching presents a shorting risk to the proximal gates. As such, a self-aligned contact (SAC) cap is typically formed on those proximal gates to prevent gate to S/D contact shorting event. Presently, selective S/D contact etching (so called SAC etching) is required but the SAC etching tends not to etch the SiN in gate cut (CT) regions.

It is therefore necessary to develop a structure and method to form CT SiN only in gate regions and not in ILD regions. This would allow for open S/D contact across CT regions.

Turning now to an overview of the aspects of the invention, one or more embodiments of the invention address the above-described shortcomings of the prior art by providing a method of semiconductor device fabrication an SAC cap is formed, a gate cut mask, which opens a gate, spacers and SiO2 ILD, is lithographically patterned, exposed material is etched to a depth deeper than a bottom of the gate, the SiO2 ILD is selectively etched to form an overhang of the mask over the remaining SiO2 ILD, an SiN liner is deposited on gate and spacer sidewalls but not on sidewalls of the SiO2 under the mask such that the SiN liner partially fills the opening made by the gate cut, the mask is removed and the remainder of the opening is filled with SiO2. This results in a semiconductor device structure having a metal gate, which is cut after formation of the SAC cap. The mask extends across the gate, the spacers and the ILD and the gate cut process removes all exposed material to a depth below the bottom of the gate. The cut region is filled with SiN liner and SiO2 gap fill material and the SiN liner is present only next to the gate and the spacer but not on the SiO2 ILD.

The above-described aspects of the invention address the shortcomings of the prior art by providing for a semiconductor device structure in which an SiN liner is not present next to the SiO2 ILD. This makes the post RMG gate cut compatible with SAC processing.

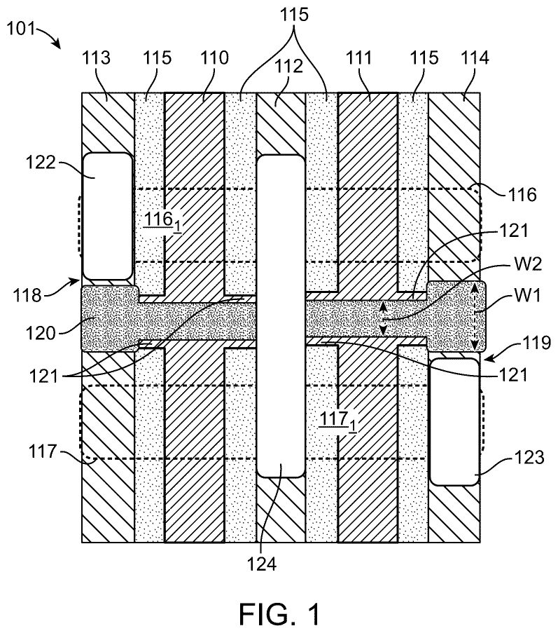

Turning now to a more detailed description of aspects of the present invention, FIG. 1 depicts a top-down view of a semiconductor device 101.

The semiconductor device 101 includes gate regions 110, 111, an interior ILD region 112, exterior ILD regions 113, 114 and spacers 115. The gate regions 110, 111 are interleaved between the interior ILD region 112 and the exterior ILD regions 113, 114. The spacers 115 are interleaved between the exterior ILD region 113 and the gate region 110, between the gate region 110 and the interior ILD region 112, between the interior ILD region 112 and the gate region 111 and between the gate region 111 and the exterior ILD region 114. The semiconductor device 101 further includes FET structures 116, 117 extending across the gate regions 110, 111, across the interior ILD region 112 and the exterior ILD regions 113, 114 and across the spacers 115 and S/D regions 118, 119 that are shared between the gate regions 110, 111 at the exterior ILD regions 113, 114. The FET structures 116, 117 can include or be provided as nanosheet stacks 1161, 1171 and can include RMG materials in the gate regions 110, 111 and epitaxy in the interior ILD region 112 and the exterior ILD regions 113, 114.

The semiconductor device 101 also includes dielectric material 120, liner material 121, first contacts 122, 123 and a second contact 124. The dielectric material 120 can include SiO2 or another similar material and extends between the FET structures 116, 117 and bisects each of the gate regions 110, 111, the interior ILD region 112, each of the exterior ILD regions 113, 114 and the spacers 115. The FET structure 116 can include or be provided as an n-doped FET (nFET) structure at a first side of the dielectric material 120 and the FET structure 117 can include or be provided as a p-doped FET (pFET) structure at a second side of the dielectric material 120. A width W1 of the dielectric material 120 bisecting the exterior ILD regions 113, 114 exceeds a width W2 of the dielectric material 120 bisecting the gate regions 110, 111. The liner material 121 can include SiN or another similar material and is disposed on opposite sides of the dielectric material 120 in the gate regions 110, 111 (and in the regions associated with the spacers 115) and not in the interior ILD region 112 or the exterior ILD regions 113, 114. The first contacts 122, 123 are formed about portions of the FET structures 116, 117 in the exterior ILD regions 113 and associated with the S/D regions 118, 119. The second contact 124 can be provided as a CT contact and extends across the dielectric material 120 at the interior ILD region 112.

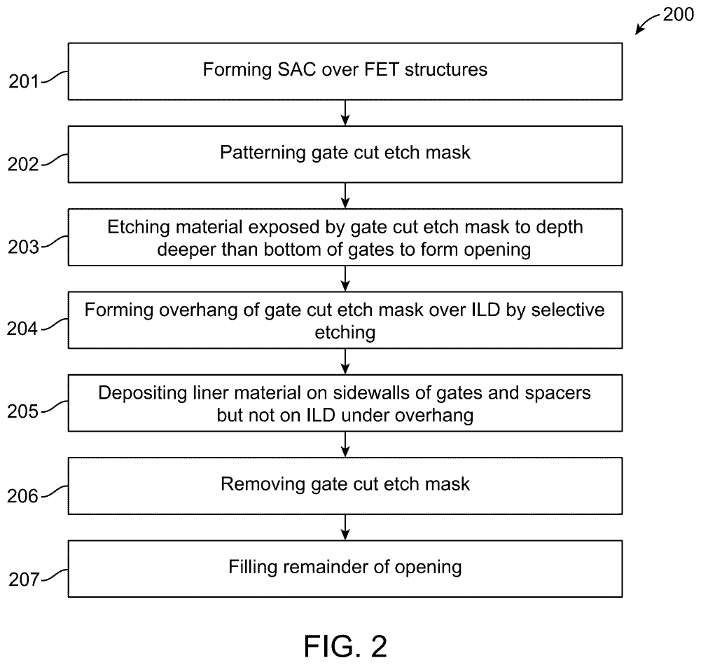

With reference to FIG. 2, a method 200 of semiconductor device fabrication is provided and includes forming an SAC over FET structures (block 201) where the FET structures include or are provided as nFET and pFET structures, respectively. The method 200 further includes patterning or lithographically patterning a gate cut etch mask for opening gates, spacers and ILD of the FET structures (block 202), etching material exposed by the gate cut etch mask to a depth deeper than a bottom of the gates to form an opening (block 203), forming an overhang of the gate cut etch mask over the ILD (block 204) by a selective etch process and depositing liner material, such as SiN or another similar material, on sidewalls of the gates and the spacers but not on the ILD under the overhang in the opening (block 205). In addition, the method 200 includes removing the gate cut etch mask (block 206) and filling a remainder of the opening with dielectric material (block 207), such as SiO2 or another similar material.

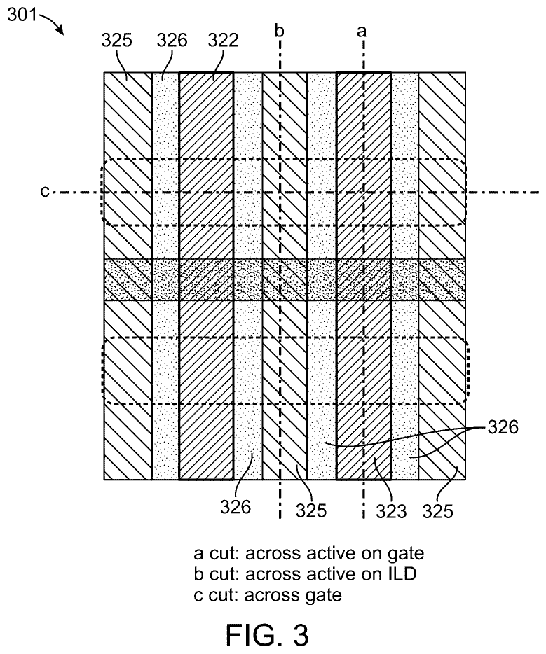

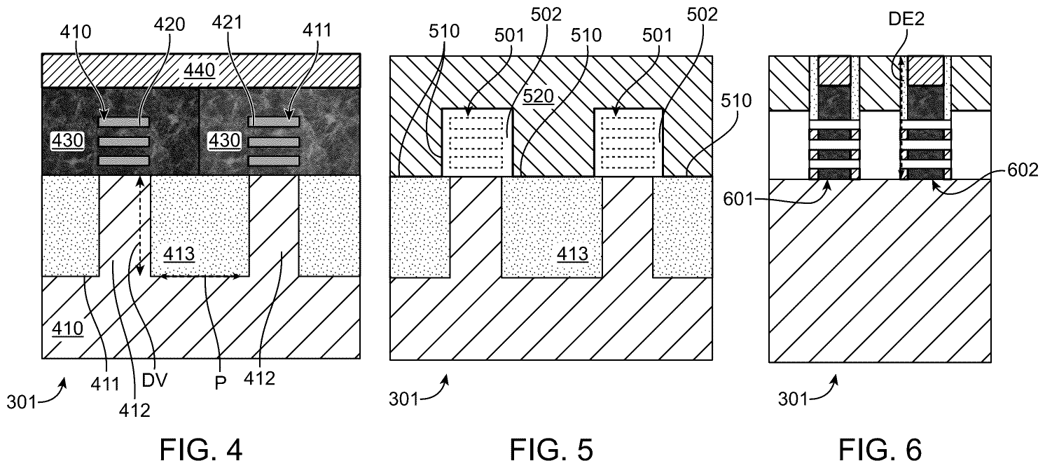

With continued reference to FIG. 2 and with additional reference to FIG. 3 and to FIGS. 4-11, the method 200 of FIG. 2 will now be described in greater detail.

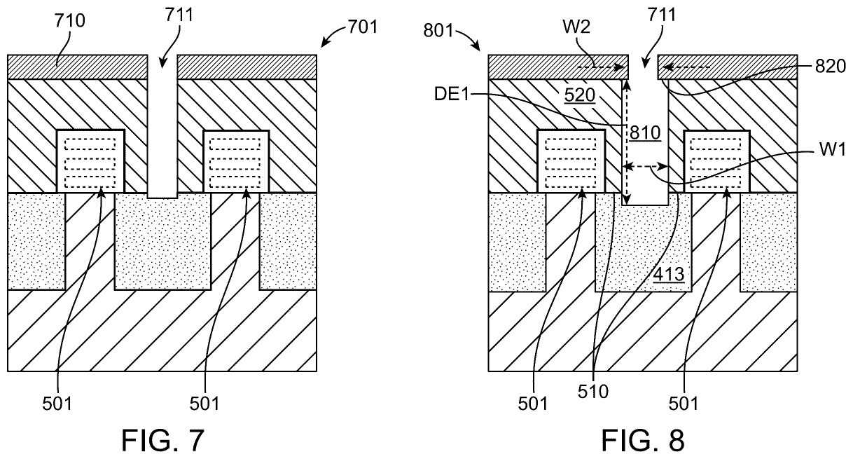

FIG. 3 depicts a top-down view of a semiconductor device assembly that is being fabricated. For reference, the “a” cross-sectional cut line of FIG. 3 corresponds to the perspective of the image in FIG. 4, the “b” cross-sectional cut line of FIG. 3 corresponds to the perspective of the image in FIG. 5 and in FIGS. 7-11 and the “c” cross-sectional cut line of FIG. 3 corresponds to the perspective of the image in FIG. 6.

As shown in FIG. 3 and in FIGS. 4-6, a semiconductor device assembly 301 at an initial stage of assembly is provided and includes a substrate 410, which is formed of semiconductor material such as silicon and which has a planar surface 411 with vertical fins 412 extending vertically upwardly along vertical dimension DV from a plane P of the planar surface 411 and with first dielectric material 413 interleaved and interposed between the vertical fins 412 (see FIG. 4). The semiconductor device 301 further includes FET structures, such as nFET structure 420 and pFET structure 421 (see FIG. 4), which are disposed on the vertical fins 412 in gate regions 322, 323 (see FIG. 3 in which the gate regions 322, 323 are illustrated as being interleaved with ILD regions 325 and spacers 326 and FIG. 1 in which the gate regions 110, 111 are illustrated as sharing S/D regions 118, 119). The FET structures can be provided as nanosheet stacks surrounded by RMG material 430 that is covered by an SAC cap 440 (see FIG. 4), as nanosheet stacks 501 surrounded by epitaxy 502 (see FIG. 5) in ILD regions 324 (see FIG. 3) and as gate structures 601, 602 with shared S/D regions (see FIG. 6). In addition, the semiconductor device assembly 301 also includes first liner material 510, which is disposed over the FET structures and at least side portions of the first dielectric material 413, and ILD 520 that is disposed on the first liner material 510 (see FIG. 5).

With reference to FIG. 7, a semiconductor device assembly 701 at a first intermediate stage of assembly is provided following gate cut hard mask patterning applied to the semiconductor device assembly 301 of FIG. 3 and of FIGS. 4-6. As shown in FIG. 7, the gate cut hard mask patterning results in formation of a gate cut hard mask 710 with an opening 711 through which the ILD 520 is exposed.

With reference to FIG. 8, a semiconductor device assembly 801 at a second intermediate stage of assembly is provided following gate cut processing and subsequent selective etching processing applied to the semiconductor device assembly 701 of FIG. 7. As shown in FIG. 8, the gate cut processing is executed through the opening 711 and results in the formation of a gate cut 810. The gate cut 810 extends through the ILD 520 and the first liner material 510 to the first dielectric material 413 at a depth DE1, which is deeper than a depth DE2 (see FIG. 6) of the gate structures 601, 602 of FIG. 6. The selecting etching is executed following the gate cut processing and can include selective SiO2 etching in lateral directions. The selective etching results in a widening of the gate cut 810 to a width W1, which exceeds a width W2 of the opening 711, and a formation of an overhang 820 of the gate cut hard mask 710.

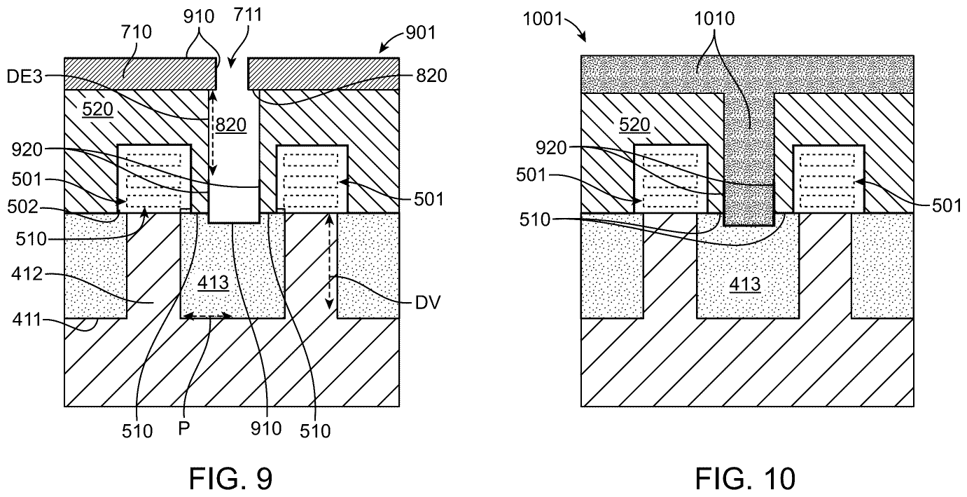

With reference to FIG. 9, a semiconductor device assembly 901 at a third intermediate stage of assembly is provided following liner or SiN deposition applied to the semiconductor device assembly 801 of FIG. 8. The liner or SiN deposition can be executed as physical vapor deposition (PVD) or another similar deposition process and results in a formation of additional liner material portions 910 and columnar liner material portions 920. The additional liner material portions 910 are disposed on exposed surfaces of the gate cut hard mask 710 and a surface of the first dielectric material 413, which is exposed through the gate cut 810. The columnar liner material portions 920 are disposed on those portions of side surfaces of the first dielectric material 413, the first liner material 510 and the ILD 520 that have a line-of-sight through the opening 711 underneath the overhang 820. That is, there is no liner or SiN deposition underneath the overhang 820 to a depth DE3. Thus, the vertical fins 412, the nanosheet stacks 501 surrounded by the epitaxy 502 of the FET structures and the columnar liner material portions 920 extend vertically upwardly along vertical dimension DV from or relative to the plane P of the planar surface 411 of the substrate 410.

With reference to FIG. 10, a semiconductor device assembly 1001 at a fourth intermediate stage of assembly is provided following liner or SiN etching, gate cut mask removal and sequential depositions of second dielectric material and chemical mechanical polishing (CMP) applied to the semiconductor device assembly 901 of FIG. 9. The semiconductor device assembly 1001 thus includes second dielectric material 1010 extending through the ILD 520 and into the first dielectric material 413 with lower portions of the second dielectric material 1010 are bounded by the columnar liner material portions 920 and upper portions of the second dielectric material 1010 are not bounded by the columnar liner material portions 920. That is, the columnar liner material portions 920 are interposed between the first dielectric material 413 and lowermost portions of the second dielectric material 1010 and between respective lower portions of the ILD 520 and the second dielectric material 1010.

As shown in FIGS. 1, 3 and 10 taken together, the second dielectric material 1010 bisects the gate regions 322, 323, the ILD regions 325 and the spacers 326. The first liner material 510 (121, in FIG. 1) surrounds the second dielectric material 1010 in the gate regions 322, 323 and in the regions associated with the spacers 326, but does not surround the second dielectric material 1010 in the ILD regions 325 including those ILD regions 325 that are associated with the S/D regions 118, 119 of FIG. 1.

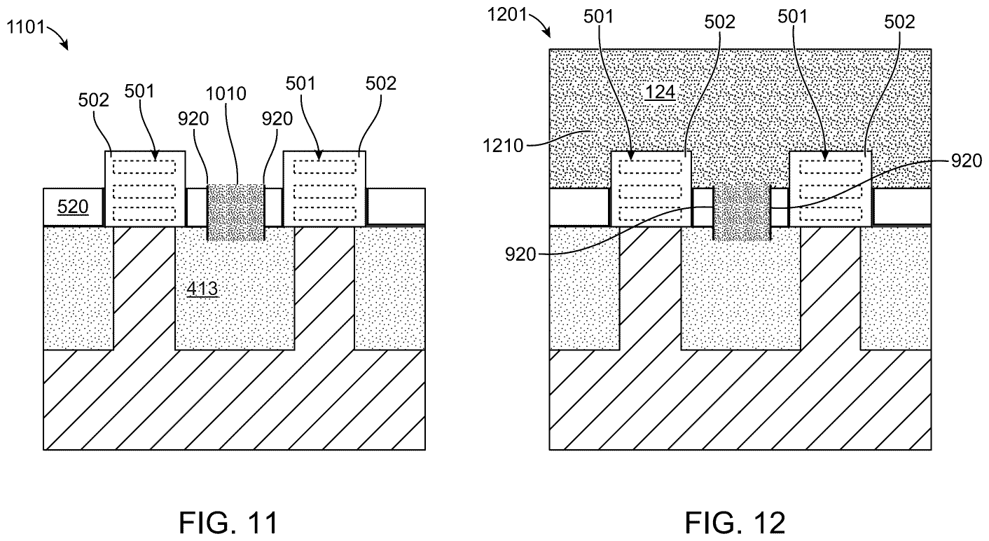

With reference back to FIG. 1 and with additional reference to FIG. 11, a semiconductor device assembly 1101 at a near-final stage of assembly is provided following S/D contact lithography and S/D contact etching applied to the semiconductor device assembly 1001 of FIG. 10. The S/D contact lithography forms masks over the gate regions 322, 323 of FIG. 3. The contact etching removes the masks as well as the ILD 510 (325 in FIG. 3) and the second dielectric material 1010 of FIG. 10 to the depth DE3 (see FIG. 9) of upper edges of the columnar liner material portions 920 and exposes the nanosheet stacks 501 surrounded by the epitaxy 502 (see FIG. 5).

With reference back to FIG. 1 and with additional reference to FIG. 12, a semiconductor device assembly 1201 at a final stage of assembly is provided following S/D contact metallization applied to the semiconductor device assembly 1101 of FIG. 11. The S/D contact metallization results in the formation of contacts 1210, such the first contacts 122, 123 and the second contact 124 of FIG. 1.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device, comprising:
gate regions interleaved between interlayer dielectric (ILD) regions;
field effect transistor (FET) structures extending across the gate regions and the ILD regions;
source and drain (S/D) regions, shared between the gate regions, at exterior ones of the ILD regions;
dielectric material between the FET structures and bisecting the gate regions and the ILD regions;
liner material disposed on opposite sides of the dielectric material in the gate regions and not in the ILD regions; and
contacts formed about the FET structures in the exterior ones of the ILD regions and across the dielectric material at an interior one of the ILD regions.

2. The semiconductor device according to claim 1, further comprising spacers interleaved between the gate regions and the ILD regions.

3. The semiconductor device according to claim 1, wherein the FET structures comprise an n-doped FET (nFET) structure at a first side of the dielectric material and a p-doped FET (pFET) structure at a second side of the dielectric material.

4. The semiconductor device according to claim 1, wherein the FET structures comprise nanosheet stacks and replacement metal gate (RMG) materials in the gate regions and epitaxy in the ILD regions.

5. The semiconductor device according to claim 1, wherein the liner material comprises silicon nitride (SiN) and the dielectric material comprises silicon dioxide (SiO2).

6. The semiconductor device according to claim 1, wherein a width of the dielectric material bisecting the exterior ones of the ILD regions exceeds a width of the dielectric material bisecting the gate regions.

7. The semiconductor device according to claim 1, wherein the contacts comprise a gate cut (CT) contact that extends across the dielectric material at the interior one of the ILD regions.

8. A method of semiconductor device fabrication, comprising:
forming a self-aligned cap (SAC) over field effect transistor (FET) structures;
patterning a gate cut etch mask for opening gates, spacers and interlayer dielectric (ILD) of the FET structures;
etching material exposed by the gate cut etch mask to a depth deeper than a bottom of the gates to form an opening;
forming an overhang of the gate cut etch mask over the ILD;
depositing a liner material on sidewalls of the gates and the spacers but not on the ILD under the overhang in the opening;
removing the gate cut etch mask; and
filling a remainder of the opening with dielectric material.

9. The method of semiconductor device fabrication according to claim 8, wherein the FET structures comprise an n-doped FET (nFET) structure and a p-doped FET (pFET) structure.

10. The method of semiconductor device fabrication according to claim 8, wherein the patterning of the gate cut etch mask comprises lithographically patterning.

11. The method of semiconductor device fabrication according to claim 8, wherein the forming of the overhang of the gate cut etch mask over the ILD comprises selective etching.

12. The method of semiconductor device fabrication according to claim 8, wherein the liner material comprises silicon nitride (SiN).

13. The method of semiconductor device fabrication according to claim 8, wherein the liner material comprises silicon dioxide (SiO2).

14. A semiconductor device, comprising:
a substrate comprising vertical fins and first dielectric material interposed between the vertical fins;
field effect transistor (FET) structures on the vertical fins;
first liner material disposed over the FET structures and side portions of the first dielectric material;
interlayer dielectric (ILD) disposed on the first liner material;
second dielectric material extending through the ILD and into the first dielectric material; and
columnar liner material interposed between the first dielectric material and the second dielectric material and between respective lower portions of the ILD and the second dielectric material.

15. The semiconductor device according to claim 14, wherein the vertical fins, the FET structures and the columnar liner material extend vertically upwardly relative to the substrate.

16. The semiconductor device according to claim 14, wherein the FET structures comprise an n-doped FET (nFET) structure and a p-doped FET (pFET) structure.

17. The semiconductor device according to claim 14, wherein the first and columnar liner materials comprise silicon nitride (SiN) and the second dielectric material comprises silicon dioxide (SiO2).

18. The semiconductor device according to claim 14, wherein:
gate regions sharing source and drain (S/D) regions are interleaved with ILD regions, and
the second dielectric material bisects the gate regions and the ILD regions.

19. The semiconductor device according to claim 18, wherein the FET structures comprise nanosheet stacks and replacement metal gate (RMG) materials in the gate regions and epitaxy in the ILD regions.

20. The semiconductor device according to claim 18, wherein there is an absence of first liner material surrounding the second dielectric material in the S/D regions.
